(19) United States
(12) Patent Application Publication
(10) Pub. No.: US 2016/0222543 A1
(43) Pub. Date: Aug. 4, 2016

(54) HEAT SHIELD BODY AND SILICON MONOCRYSTRAL INGOT MANUFACTURING DEVICE COMPRISING SAME

(71) Applicant: LG SILTRON INCORPORATED, Gumi-si (KR)

(72) Inventors: Jung Hyun KONG, Gyeongsangbuk-do (KR); Sang Jun LEE, Gyeongsangbuk-do (KR)

(21) Appl. No.: 15/022,520

(22) PCT Filed: Sep. 15, 2014
(86) PCT No.: PCT/KR2014/008558

§ 371 Date: Mar. 16, 2016

(30) Foreign Application Priority Data
Sep. 16, 2013 (KR) 10-2013-0111259

(51) Int. Cl. C30B 15/14; C30B 29/06

(52) U.S. Cl. CPC C30B 15/14; C30B 29/06

(57) ABSTRACT

An embodiment provides a heat shield body comprising: a first portion arranged to surround a through-hole in a center area; a scale arranged on the first portion; and a second portion arranged to extend from the first portion to a periphery.

### TECHNICAL FIELD

Embodiments relate to an apparatus for manufacturing a silicon single crystal ingot and a heat shield used therein, and more particularly to accurate measurement of surface level of a silicon melt in a silicon single crystal ingot manufacturing apparatus.

### BACKGROUND ART

Typically, a silicon wafer is manufactured using a method including a single crystal growth process for producing a single crystal (ingot), a slicing process for slicing the ingot, thereby obtaining a wafer having a thin disc shape, a lapping process for removing mechanical damage induced in the wafer due to the slicing process, a polishing process for polishing surfaces of the wafer, and a cleaning process for further polishing the polished surfaces of the wafer while removing a polishing agent or foreign matter attached to the wafer.

The process for growing a silicon single crystal ingot in the above-mentioned method may be carried out by heating, at high temperature, a growth furnace into which a highly pure silicon raw material is charged, to melt the raw material, and then growing the silicon melt into a silicon single crystal ingot, using a Czochralski method (hereinafter, referred to as a “CZ method”) or the like. A method disclosed in this disclosure may be applied to the CZ method in which a seed crystal is positioned over a silicon melt, to grow a single crystal ingot.

For growth of a silicon single crystal ingot using the CZ method, polysilicon is charged into a crucible, and is then melted. In order to heat the crucible, a resistive heater is arranged to surround outer peripheral and bottom walls of the crucible. Heating of the crucible is achieved using radiant heat generated during operation of the heater.

In this case, it is necessary to check growth state of a single crystal ingot grown from a silicon melt and surface level of the silicon melt. In connection with this, it is difficult to accurately measure surface level of the silicon melt with the naked eye.

To solve this problem, measurement of silicon melt surface level may be carried out using a separate device. In this case, however, the measurement may interfere with orbital motion of a silicon single crystal ingot. For this reason, it may be impossible to accurately measure surface level of a silicon melt.

Japanese Patent Application No. 2006-050299 discloses measurement of a silicon melt using a reflective plate such as a mirror. In this case, however, an oxide produced within an ingot manufacturing apparatus may be deposited on the mirror and, as such, measurement error or sensor failure may occur.

### DISCLOSURE

### Technical Problem

An object of the present invention devised to solve the problem lies in embodiments capable of accurately measuring surface level of a silicon melt in a silicon single crystal ingot manufacturing apparatus.

### Technical Solution

The object of the present invention can be achieved by providing a heat shield including a first section disposed around a central through hole, scales arranged at the first section, and a second section extending outwards from an outer circumferential edge of the first section.

The scales may be arranged at a bottom surface of the first section.

The scales may be arranged at an inner peripheral surface of the first section.

The scales may be arranged at each of at least two areas having different levels in the first section.

The scales may be arranged at each of different horizontal areas in the first section.

The scales arranged at each of the different horizontal areas in the first section may be connected to take a line shape.

The scales arranged at each of the different horizontal areas in the first section may be separate from each other while taking a dot shape.

The different horizontal areas may be arranged to face each other at opposite sides of the through hole.

The scales may be formed at the first section while having an engraved shape.

The scales may be formed at the first section while having an embossed shape.

The second section may be inclined from the first section by a predetermined angle.

In another aspect, provided herein is an apparatus for manufacturing a silicon single crystal ingot, including a chamber, a crucible disposed within the chamber, to receive a silicon melt, a heater disposed within the chamber, to heat the crucible, and a heat shield arranged over the crucible, to shield heat flowing from the silicon melt toward a single crystal ingot grown from the silicon melt, the heat shield comprising a first section disposed around a central through hole, scales arranged at the first section, and a second section extending outwards from an outer circumferential edge of the first section.

### Advantageous Effects

In the above-described heat shield and the silicon single crystal ingot manufacturing apparatus including the same, even when the silicon single crystal ingot performs an orbital motion, or an oxide is deposited on a surface of the heat shield or the like, it may be possible to check the surface level of the silicon melt based on images reflected from the heat shield. Since scales are formed in different areas on the inner peripheral surface of the shield, respectively, the observer may observe reflected images even when the position of the observer is shifted.

### DESCRIPTION OF DRAWINGS

FIG. 1 is a view illustrating an embodiment of a silicon single crystal ingot growing apparatus;

FIGS. 2A to 2D are views illustrating an embodiment of the heat shield of FIG. 1;

FIGS. 3A to 3C are views illustrating another embodiment of the heat shield of FIG. 1;

FIGS. 4A to 4D are views illustrating embodiments of scales of the heat shield; and

FIG. 5 is a view illustrating a grown silicon single crystal ingot and scale images of the heat shield.

### BEST MODE

The accompanying drawings, which are included to provide a further understanding of the invention and are incorporated in and constitute a part of this application, illustrate embodiments of the invention and together with the description serve to explain the principle of the invention.

In the following description of the embodiments, it will be understood that, when an element is referred to as being “on” or “under” another element, it can be directly on or under another element or can be indirectly formed such that an intervening element is also present. In addition, the terms “on” or “under” as used herein may encompass not only an upward direction with respect to the associated element, but also a downward direction with respect to the associated element.

In the drawings, the thickness or size of each layer is exaggerated, omitted, or schematically illustrated for convenience of description and clarity. In addition, the size or area of each constituent element does not entirely reflect the actual size thereof.

FIG. 1 is a view illustrating an embodiment of a silicon single crystal ingot growing apparatus.

The silicon single crystal ingot growing apparatus according to the illustrated embodiment, namely, an apparatus 100, includes a chamber 10 defined therein with a space for growing a silicon single crystal ingot 14 from a silicon (Si) melt, crucibles 20 and 22 for receiving the silicon melt, a heater 40 for heating the crucibles 20 and 22, a heat shield 200 arranged over the crucible 20, to shield heat from the silicon melt, a seed chuck 18 for fixing a seed (not shown) for growth of the silicon single crystal ingot 14, and a rotating shaft 30 for rotating the crucibles 20 and 22 while vertically moving the crucibles 20 and 22.

The chamber 10 provides a space in which desired processes for forming a silicon single crystal ingot from a silicon melt are carried out. A crucible may be disposed within the chamber 10, to receive a silicon melt. A cooling water tube, which is made of tungsten (W) or molybdenum (Mo), may be provided. Of course, the cooling water tube is not limited to the above-described material.

The crucible may include a quartz crucible, namely, the crucible 20, directly contacting the silicon melt, and a graphite crucible, namely, the crucible 22, supporting the quartz crucible 20 while surrounding an outer surface of the quartz crucible 20.

A radiant heat insulator may be provided within the chamber 10, to prevent heat of the heater 40 from being discharged outwards. In the illustrated embodiment, only a heat shield 200 disposed over the crucibles 20 and 22 is illustrated. However, insulators may also be arranged around peripheral and bottom walls of the crucibles 20 and 22.

The heater 40 melts a silicon raw material having various shapes, which is placed within the crucibles 20 and 22, to produce a silicon melt.

The heater 40 may include a plurality of heater units arranged to surround the peripheral and bottom walls of the crucibles 20 and 22. That is, plural heater units may be arranged around the peripheral and bottom walls of the crucibles 20 and 22, to surround the crucibles 20 and 22.

A support 20 is centrally disposed at the bottom wall of the crucibles 20 and 22, to support the crucibles 20 and 22. The silicon (Si) melt is partially solidified from the seed, to grow a silicon single crystal ingot, namely, the ingot 14.

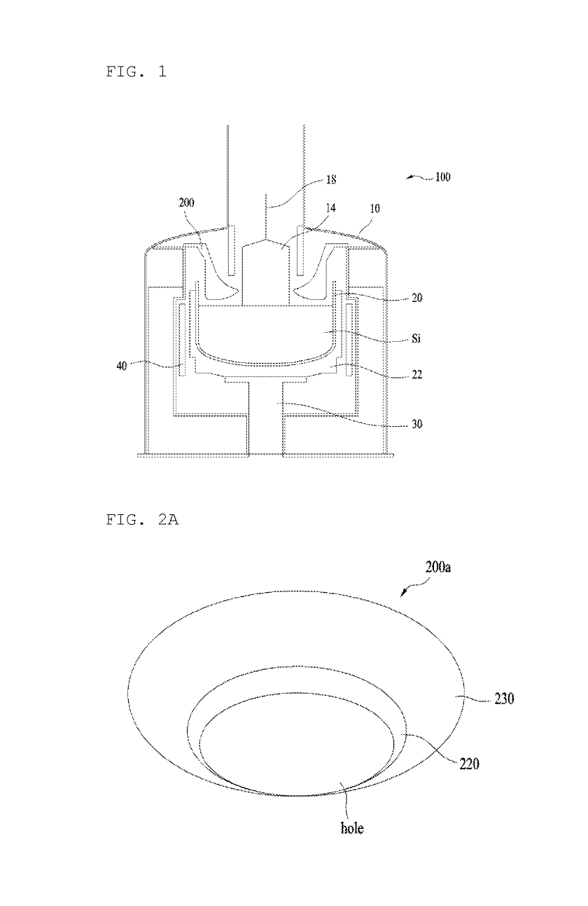

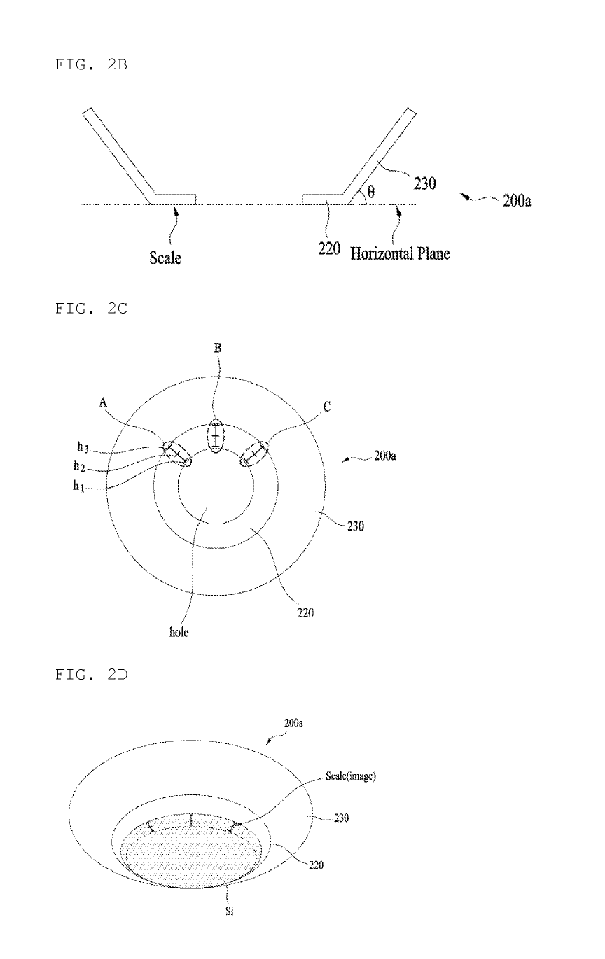

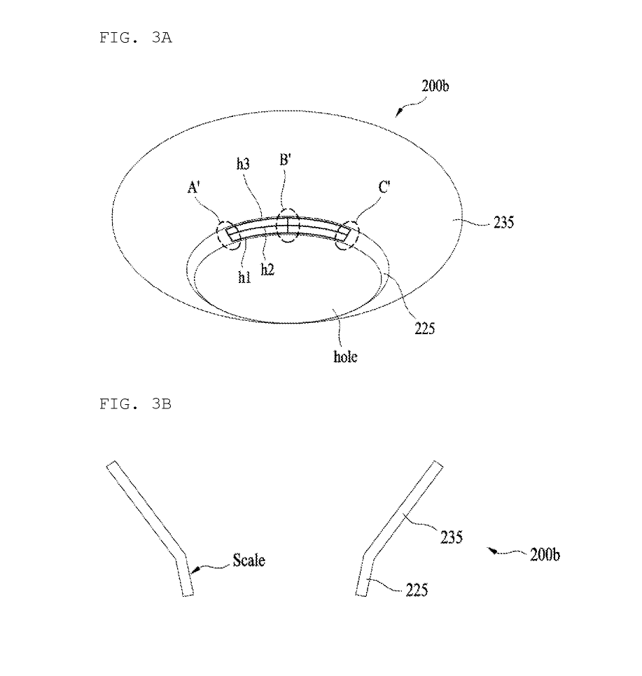

FIGS. 2A to 2D are views illustrating an embodiment of the heat shield of FIG. 1.

FIG. 2A shows a perspective view of a heat shield 200a. FIG. 2B shows a sectional view of the heat shield 200a. FIG. 2C shows a bottom view of the heat shield 200a. The heat shield 200a may be made of carbon, tungsten, molybdenum, etc.

The heat shield 200a includes a first section 220 disposed around a central through hole, and a second section 230 extending outwards from an outer circumferential edge of the first section 220.

The second section 230 may be inclined from the first section 220 by a predetermined angle. As illustrated in FIG. 2B, the second section 230 may be inclined from a horizontal plane indicated by a dotted line by a predetermined angle θ (60 to 120°).

Scales h₁, h₂, and h₃ are arranged in different areas of a bottom surface of the first section 220, respectively. In order to achieve determination of surface level of a silicon melt based on scale images formed on a surface of the silicon melt through reflection of light from the scales h₁, h₂, and h₃, it is necessary to arrange the scales h₁, h₂, and h₃ in each of at least two different areas. Here, the “bottom surface” means a surface of the first section 220 facing the silicon melt.

In the above-described silicon single crystal ingot manufacturing apparatus, the scales h₁, h₂, and h₃ may be arranged in each of at least two areas on the bottom surface of the first section 220 in order to enable the observer to measure surface level of the silicon melt even at different positions. In particular, the scales h₁, h₂, and h₃ may be arranged in separate horizontal areas on the bottom surface of the first section 220.

In the illustrated embodiment, three scales h₁, h₂, and h₃ are arranged at different levels in each of three areas A, B, and C, respectively. The three scales h₁, h₂, and h₃ may be separate from one another while taking a dot shape. In another embodiment, the three scales h₁, h₂, and h₃, may be connected to take a line shape.

FIG. 2D illustrates the heat shield 200a disposed over the silicon melt. Light reflected from the scales (not shown) on the bottom surface of the first section 220 of the heat shield 200a is incident upon the surface of the silicon melt and, as such, images of the scales are formed on certain areas of the surface of the silicon melt. Accordingly, it may be possible to check surface level of the silicon melt by observing positions of the scale images formed on the surface of the silicon melt through reflection of the scale images.

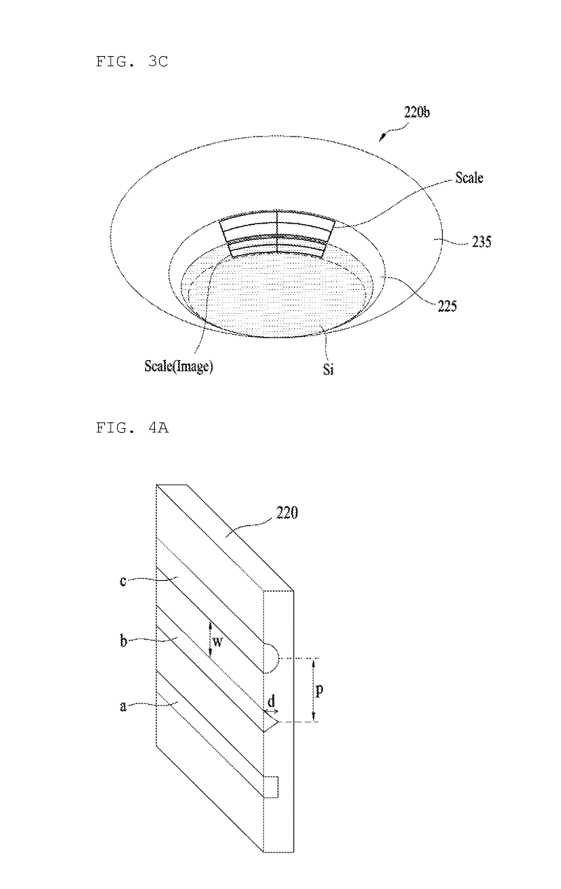

FIGS. 3A to 3C are views illustrating another embodiment of the heat shield of FIG. 1.

FIG. 3A shows a perspective view of a heat shield 200b. FIG. 3B shows a sectional view of the heat shield 200b.

The heat shield 200b according to this embodiment is similar to the embodiment illustrated in FIGS. 2A to 2D, except that a first section 225 is arranged without being perpendicular to the surface of the silicon melt, and scales are arranged at an inner peripheral surface of the first section 225.

The heat shield 200b includes the first section 225, which is disposed around a central through hole, and a second section 235 extending outwards from an outer circumferential edge of the first section 225. The first section 225 and second section 235 may prevent heat from being discharged from the crucible and, as such, function as a hot zone. As in the previous embodiment, the second section 235 may be arranged to be inclined 60 to 120° from the first section 225

Scales h₁, h₂, and h₃ are arranged in three different areas on the inner peripheral surface of the first section 225, respectively. In order to achieve determination of surface level of a silicon melt based on scale images formed on a surface of the silicon melt through reflection of light from the scales h₁, h₂, and h₃, it is necessary to arrange the scales h₁, h₂, and h₃ in each of at least two different areas.

In the above-described silicon single crystal ingot manufacturing apparatus, the scales h₁, h₂, and h₃ may be arranged in each of at least two areas having different levels on the inner peripheral surface of the first section 225 in order to enable the observer to measure surface level of the silicon melt even at different positions. In particular, the scales h₁, h₂, and h₃ may be arranged in separate horizontal areas on the inner peripheral surface of the first section 225.

In the illustrated embodiment, three scales h₁, h₂, and h₃ are arranged at different levels in each of three horizontally arranged areas A′, B′, and C′, respectively. The three scales h₁, h₂, and h₃ may be connected to take a line shape. In another embodiment, the three scales h₁, h₂, and h₃ may be separate from one another while having a dot shape.

FIG. 3C illustrates the heat shield 200b disposed over the silicon melt. Light reflected from the scales on the inner peripheral surface of the first section 225 of the heat shield 200b is incident upon the surface of the silicon melt and, as such, images of the scales are formed on certain areas of the surface of the silicon melt. Accordingly, it may be possible to check surface level of the silicon melt by observing positions of the scale images formed on the surface of the silicon melt through reflection of the scale images.

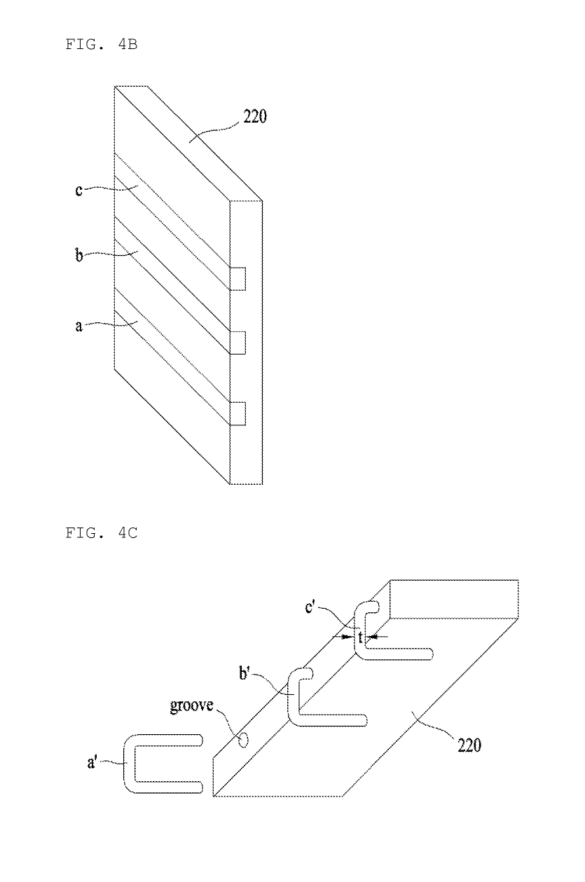

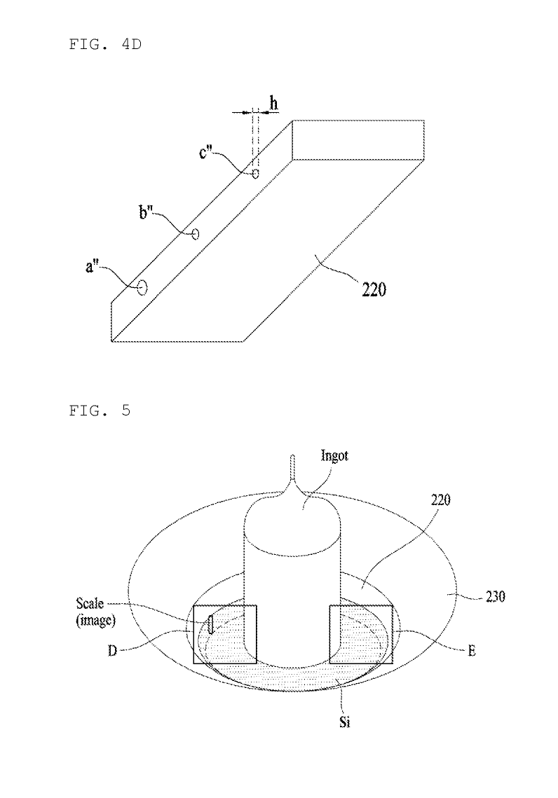

FIGS. 4A to 4D are views illustrating embodiments of scales of the heat shield.

In the embodiment illustrated in FIG. 4A, scales a, b, and c are formed to have an engraved shape through depression of desired portions of the inner peripheral surface of the first section 220. The scales a, b, and c may have a square cross-section a, a triangular cross-section b, and a semicircular cross-section c, respectively. Although scales a, b, and c having different shapes are arranged at the inner peripheral surface of the first section 220 in the case of FIG. 4A, scales having the same shape may be arranged at the inner peripheral surface of the first section 220.

Although the scales a, b, and c have different shapes in the case of FIG. 4A, scales having the same shape, for example, scales a, may be arranged, as in the case of FIG. 4B. In addition, the shape of the scales a may be triangular or semicircular, rather than square.

In an embodiment of FIG. 4C, scales a′, b′, and c′ are formed to have an embossed shape. In detail, grooves are formed at different levels on the inner peripheral surface of the first section 220, respectively. The three scales a′, b′, and c′ are inserted into respective grooves.

Although the scales a′, b′, and c′ are inserted into respective grooves of the first section 220 in the case of FIG. 4C, scales a″, b″, and c″ may be formed to be integrated with the first section 220, as illustrated in FIG. 4D. In this case, the height of the scales a″, b″, and c″, namely, a height h, may be equal to the thickness of the scales a′, b′, and c′ in the case of FIG. 4C, namely, a thickness t.

The depth of the scales formed to have an engraved shape in the case of FIG. 4A, namely, a depth d, and the thickness t of the scales formed to have an embossed shape in the case of FIG. 4C may be appropriately determined within a range enabling the observer to measure surface level of the silicon melt by observing scale images formed on the surface of the silicon melt through reflection of the scale images. The depth d and thickness t may be 1 to 3 cm. When the depth t and the thickness t are excessively small, it may be difficult for the observer to identify scale images. On the other hand, when the depth t and the thickness t are excessively great, it may be difficult for the observer to accurately measure surface level of the silicon melt.

Meanwhile, the distance between adjacent ones of the scales a, b, and c, namely, a distance w, may be 5 to 10 cm. When the distance w is excessively small, it may be difficult for the observer to discriminate scale images of the scales a, b, and c from one another. On the other hand, when the distance w is excessively great, it may be difficult for the observer to accurately measure surface level of the silicon melt based on scale images formed on the surface of the silicon melt through reflection of the scale images. The pitch of the scales a, b, and c in the case of FIG. 4A, namely, a pitch p, may be greater than the distance w.

FIG. 5 is a view illustrating a grown silicon single crystal ingot and scale images of the heat shield.

As illustrated in FIG. 5, the surface of the silicon melt may be lowered as a silicon single crystal ingot is grown. Images of scales formed at the first section 220 are incident upon the surface of the silicon melt through reflection thereof and, as such, may be observed by the observer. In this case, the scale images observed by the observer may be formed at two facing regions D and E, respectively.

Accordingly, even when the silicon single crystal ingot performs an orbital motion, or an oxide is deposited on a surface of the heat shield or the like, it may be possible to check the surface level of the silicon melt based on images reflected from the heat shield. Since scales are formed in different areas on the inner peripheral surface of the shield, respectively, the observer may observe reflected images even when the position of the observer is shifted.

It will be apparent to those skilled in the art that various modifications and variations can be made in the present invention without departing from the spirit or scope of the invention.

Thus, it is intended that the present invention cover the modifications and variations of this invention provided they come within the scope of the appended claims and their equivalents.

### INDUSTRIAL APPLICABILITY

The heat shield according to each of the above-described embodiments and the silicon single crystal ingot manufacturing apparatus including the same may be used in a process of manufacturing a silicon wafer.

1. A heat shield comprising:
a first section disposed around a central through hole;
scales arranged at the first section; and
a second section extending outwards from an outer circumferential edge of the first section.

2. The heat shield according to claim 1, wherein the scales are arranged at a bottom surface of the first section.

3. The heat shield according to claim 1, wherein the scales are arranged at an inner peripheral surface of the first section.

4. The heat shield according to claim 1, wherein the scales are arranged at each of at least two areas having different levels in the first section.

5. The heat shield according to claim 1, wherein the scales are arranged at each of different horizontal areas in the first section.

6. The heat shield according to claim 1, wherein the scales arranged at each of the different horizontal areas in the first section are spaced apart from each other by 1 to 5 cm.

7. The heat shield according to claim 5, wherein the scales arranged at each of the different horizontal areas in the first section are connected to take a line shape.

8. The heat shield according to claim 5, wherein the scales arranged at each of the different horizontal areas in the first section are separate from each other while taking a dot shape.

9. The heat shield according to claim 5, wherein the different horizontal areas are arranged to face each other at opposite sides of the through hole.

10. The heat shield according to claim 1, wherein the scales are formed at the first section while having an engraved shape.

11. The heat shield according to claim 10, wherein the scales having the engraved shape have a depth of 1 to 3 cm from the first section.

12. The heat shield according to claim 1, wherein the scales are formed at the first section while having an embossed shape.

13. The heat shield according to claim 12, wherein the scales having the embossed shape protrudes from the first section by 1 to 3 cm.

14. The heat shield according to claim 1, wherein the second section is inclined from the first section by a predetermined angle.

15. An apparatus for manufacturing a silicon single crystal ingot, comprising:
a chamber;
a crucible disposed within the chamber, to receive a silicon melt;
a heater disposed within the chamber, to heat the crucible; and
a heat shield arranged over the crucible, to shield heat flowing from the silicon toward a single crystal ingot grown from the silicon melt, the heat shield comprising a first section disposed around a central through hole, scales arranged at the first section, and a second section extending outwards from an outer circumferential edge of the first section.

16. The apparatus according to claim 15, wherein the scales are arranged at a bottom surface of the first section or an inner peripheral surface of the first section.

17. The apparatus according to claim 15, wherein the scales are arranged at each of at least two areas having different levels in the first section.

18. The apparatus according to claim 15, wherein the scales are arranged at each of different horizontal areas in the first section.

19. The apparatus according to claim 18, wherein the scales arranged at each of the different horizontal areas in the first section are connected to take a line shape or are separate from each other while taking a dot shape.

20. The apparatus according to claim 18, wherein the different horizontal areas are arranged to face each other at opposite sides of the through hole.
